(19) United States
(12) Patent Application Publication
(10) Pub. No.: US 2026/0238224 A1
(43) Pub. Date: Aug. 13, 2026

(54) INTEGRATOR AND SIGMA-DELTA ANALOG-TO-DIGITAL CONVERTER

(71) Applicant: Realtek Semiconductor Corp., HsinChu (TW)

(72) Inventor: Chih-Chiang Wang, HsinChu (TW)

(73) Assignee: Realtek Semiconductor Corp., HsinChu (TW)

(21) Appl. No.: 19/406,831

(22) Filed: Dec. 2, 2025

(30) Foreign Application Priority Data
Feb. 7, 2025 (TW) 114104611

(51) Int. Cl. H03M 3/00

(52) U.S. Cl. CPC H03M 3/496; H03M 3/422; H03M 3/464

(57) ABSTRACT

The present invention provides an integrator used in a sigma-delta analog-to-digital converter, which includes a sampling circuit and an integrating circuit. By designing a specific switch with a charge averaging function in the sampling circuit, the voltage level of terminals of the multiple sampling capacitors can be averaged to be close to a voltage level of the input signal to be sampled before a sampling stage, so that the input buffer only requires lower drive capability to charge or discharge the sampling capacitor. Thus the power consumption of the input buffer can be reduced.

### BACKGROUND OF THE INVENTION

### 1.Field of the Invention

The present invention relates to a sigma-delta analog-to-digital converter.

### 2. Description of the Prior Art

In a sigma-delta analog-to-digital converter, an input buffer is typically implemented to receive an input signal for driving the subsequent integrator. However, when the integrator is a switched-capacitor integrator, the input buffer requires a stronger driving capability, thus leading to higher power consumption.

### SUMMARY OF THE INVENTION

Therefore, one of the objectives of the present invention is to provide an integrator that allows the input buffer to drive the integrator with only a weaker driving capability, thereby solving the problems described in the prior art.

In one embodiment of the present invention, an integrator comprising a sampling circuit and an integration circuit is disclosed. The sampling circuit is configured to perform a sampling operation on a first signal to generate a sampled signal, and the integration circuit is configured to perform an integration operation on the sampled signal to generate a second signal. The sampling circuit comprises a first circuit, a second circuit and a first specific switch. The first circuit comprises a first switch, a second switch, a third switch, a fourth switch, and a first sampling capacitor, wherein the first switch is coupled between a first terminal and a common-mode voltage, the second switch is coupled between the first terminal and a sampling circuit output terminal, the third switch is coupled between a sampling circuit input terminal and a second terminal, the fourth switch is coupled between the second terminal and a first voltage, and the first sampling capacitor is coupled between the first terminal and the second terminal. The second circuit comprises a first switch, a second switch, a third switch, a fourth switch, and a second sampling capacitor of the second circuit, wherein the first switch is coupled between a first terminal of the second circuit and the common-mode voltage, the second switch is coupled between the first terminal and the sampling circuit output terminal, the third switch is coupled between the sampling circuit input terminal and a second terminal of the second circuit, the fourth switch is coupled between the second terminal and a second voltage, and the second sampling capacitor is coupled between the first terminal and the second terminal. The first specific switch is coupled between the second terminal of the first circuit and the second terminal of the second circuit.

In one embodiment of the present invention, a recording path is disclosed. The recording path comprises an input buffer, an adder, two integrators, a quantization circuit and a digital-to-analog converter. The input buffer is configured to receive an input signal to generate a buffered input signal. The adder is configured to subtract a feedback signal from the buffered input signal to generate a first signal. The first integrator is configured to perform sampling and integration operations on the first signal to generate a second signal. The quantization circuit, configured to generate an output signal according to the second signal. The digital-to-analog converter is configured to perform a digital-to-analog conversion operation on the output signal to generate the feedback signal. In addition, each of the integrators comprising a sampling circuit and an integration circuit is disclosed. The sampling circuit is configured to perform a sampling operation on a first signal to generate a sampled signal, and the integration circuit is configured to perform an integration operation on the sampled signal to generate a second signal. The sampling circuit comprises a first circuit, a second circuit and a first specific switch. The first circuit comprises a first switch, a second switch, a third switch a fourth switch, and a first sampling capacitor, wherein the first switch is coupled between a first terminal and a common-mode voltage, the second switch is coupled between the first terminal and a sampling circuit output terminal, the third switch is coupled between a sampling circuit input terminal and a second terminal, the fourth switch is coupled between the second terminal and a first voltage, and the first sampling capacitor is coupled between the first terminal and the second terminal. The second circuit comprises a first switch, a second switch, a third switch, a fourth switch, and a second sampling capacitor of the second circuit, wherein the first switch is coupled between a first terminal of the second circuit and the common-mode voltage, the second switch is coupled between the first terminal and the sampling circuit output terminal, the third switch is coupled between the sampling circuit input terminal and a second terminal of the second circuit, the fourth switch is coupled between the second terminal and a second voltage, and the second sampling capacitor is coupled between the first terminal and the second terminal. The first specific switch is coupled between the second terminal of the first circuit and the second terminal of the second circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a sigma-delta analog-to-digital converter according to an embodiment of the present invention.

FIG. 2 is a schematic diagram of an integrator according to an embodiment of the present invention.

FIG. 3 is a schematic diagram of a plurality of clock signals according to an embodiment of the present invention.

### DETAILED DESCRIPTION

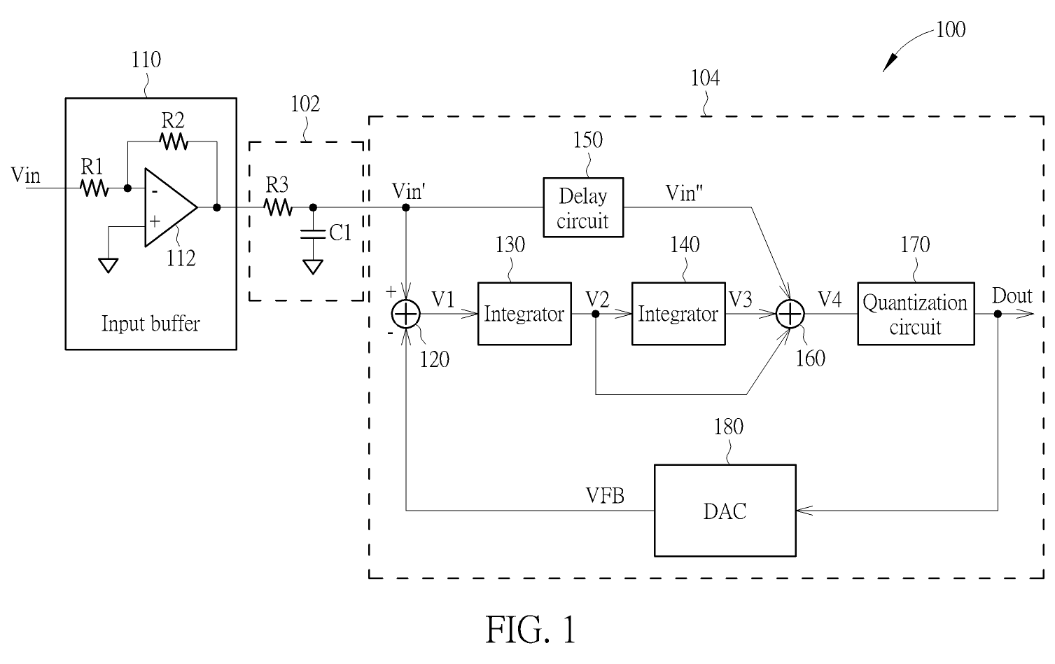

FIG. 1 is a schematic diagram of a recording path 100 according to an embodiment of the present invention, wherein the recording path 100 is used to process an input signal Vin to generate an output signal Dout. As shown in FIG. 1, the recording path 100 includes an input buffer 110, a low-pass filter 102, and a sigma-delta analog-to-digital converter (ADC) 104. The sigma-delta ADC 104 includes an adder 120, two integrators 130 and 140, a delay circuit 150, an adder 160, a quantization circuit 170, and a digital-to-analog converter (DAC) 180. The input buffer 110 includes an amplifier 112, an input resistor R1, and a feedback resistor R2 coupled between an input terminal and an output terminal of the amplifier 112. The low-pass filter 102 includes an output resistor R3 and an output capacitor C1. In this embodiment, the sigma-delta ADC 104 can be implemented in any electronic device that requires analog-to-digital conversion, such as an electronic device with a microphone, and is used to convert an analog audio signal from the microphone into a digital audio signal.

In the operation of the recording path 100, the input buffer 110 receives the input signal Vin to generate a buffered input signal Vin’, and the buffered input signal Vin’ passes through the delay circuit 150 to generate a delayed input signal Vin”. Simultaneously, the adder 120 subtracts a feedback signal VFB from the buffered input signal Vin’ to generate a first signal V1, the integrator 130 performs sampling and integration operations on the first signal V1 to generate a second signal V2, and the integrator 140 performs sampling and integration operations on the second signal V2 to generate a third signal V3. Next, the adder 160 performs a weighted summation operation on the delayed input signal Vin”, the second signal V2, and the third signal V3 to generate a fourth signal V4. The quantization circuit 170 may include multiple comparators and an encoding circuit, which are used to convert the fourth signal V4 into the output signal Dout, wherein the output signal Dout is a multi-bit digital signal. In one embodiment, the quantization circuit 170 can quantize the fourth signal V4 into eight quantization levels +7, +5, +3, +1, -1, -3, -5, -7, and the generated output signal Dout is a three-bit digital signal. For example, the three bits D1, D2, D3 of the output signal Dout corresponding to the quantization levels +7, +5, +3, +1, -1, -3, -5, -7 can be (1, 1, 1), (1, 1, 0), (1, 0, 1), (1, 0, 0), (0, 1, 1), (0, 1, 0), (0, 0, 1), (0, 0, 0), respectively. Then, the digital-to-analog converter 180 performs a digital-to-analog conversion operation on the output signal Dout to generate the feedback signal VFB.

Furthermore, the sigma-delta ADC 104 in FIG. 1 is merely provided for illustrative purposes and is not intended as a limitation of the present invention. For example, there can be different circuit designs between the integrator 130 and the quantization circuit 170, that is, as long as the quantization circuit 170 can generate the output signal Dout based on the fourth signal V4.

It is noted that since the operation of the sigma-delta ADC 104 is well known to those skilled in the art, and the focus of the present invention is on the circuit design of the integrator 130, a detailed description of other components of the sigma-delta ADC 104 will not be provided herein.

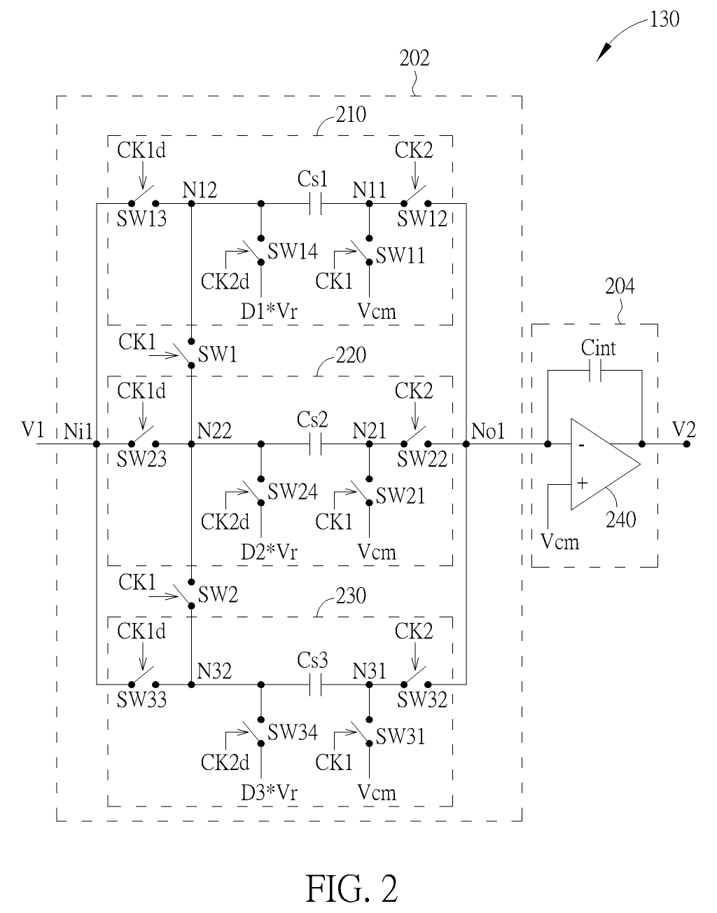

FIG. 2 is a schematic diagram of the integrator 130 according to an embodiment of the present invention. As shown in FIG. 2, the integrator 130 includes a sampling circuit 202 and an integration circuit 204. The sampling circuit 202 includes a first circuit 210, a second circuit 220, a third circuit 230, a first specific switch SW1 and a second specific switch SW2. In this embodiment, the first circuit 210 includes a first switch SW11, a second switch SW12, a third switch SW13, a fourth switch SW14, and a first sampling capacitor Cs1, wherein the first switch SW11 is coupled between a first terminal N11 and a common-mode voltage Vcm, the second switch SW12 is coupled between the first terminal N11 and a sampling circuit output terminal No1, the third switch SW13 is coupled between a sampling circuit input terminal Ni1 and a second terminal N12, the fourth switch SW14 is coupled between the second terminal N12 and a first voltage D1*Vr, and the first sampling capacitor Cs1 is coupled between the first terminal N11 and the second terminal N12. The second circuit 220 includes a first switch SW21, a second switch SW22, a third switch SW23, a fourth switch SW24, and a second sampling capacitor Cs2, wherein the first switch SW21 is coupled between a first terminal N21 and the common-mode voltage Vcm, the second switch SW22 is coupled between the first terminal N21 and the sampling circuit output terminal No1, the third switch SW23 is coupled between the sampling circuit input terminal Ni1 and a second terminal N22, the fourth switch SW24 is coupled between the second terminal N22 and a second voltage D2*Vr, and the second sampling capacitor Cs2 is coupled between the first terminal N21 and the second terminal N22. The third circuit 230 includes a first switch SW31, a second switch SW32, a third switch SW33, a fourth switch SW34, and a third sampling capacitor Cs3, wherein the first switch SW31 is coupled between a first terminal N31 and the common-mode voltage Vcm, the second switch SW32 is coupled between the first terminal N31 and the sampling circuit output terminal No1, the third switch SW33 is coupled between the sampling circuit input terminal Ni1 and a second terminal N32, the fourth switch SW34 is coupled between the second terminal N32 and a third voltage D3*Vr, and the third sampling capacitor Cs3 is coupled between the first terminal N31 and the second terminal N32. In FIG. 2, “Vr” can be a reference voltage with a fixed voltage level, and D1, D2, and D3 are the three bits of the output signal Dout, respectively.

The integration circuit 204 includes an amplifier 240 and an integration capacitor Cint, wherein the integration capacitor Cint is coupled between a negative input terminal and an output terminal of the amplifier 240, and a positive input terminal of the amplifier 240 is coupled to the common-mode voltage Vcm.

It should be noted that the number of sampling capacitors and corresponding switches shown in FIG. 2 is merely provided for illustrative purposes and is not intended as a limitation of the present invention. In other embodiments, if the output signal Dout has only two bits, the third circuit 230 can be removed from the sampling circuit 202; whereas if the output signal Dout has four bits, the sampling circuit 202 can further include a fourth circuit, wherein the architecture of the fourth circuit is the same as the first circuit 210, the second circuit 220, or the third circuit 230.

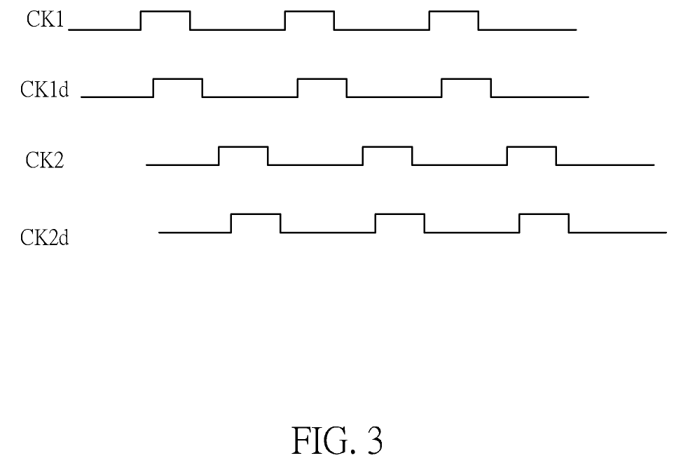

In this embodiment, referring to FIG. 3 together, the first switches SW11, SW21, and SW31 in the first circuit 210, the second circuit 220, and the third circuit 230 are controlled by a first clock signal CK1, and the second switches SW12, SW22, and SW32 in the first circuit 210, the second circuit 220, and the third circuit 230 are controlled by a second clock signal CK2, wherein the first clock signal CK1 and the second clock signal CK2 do not have a high voltage level at the same time, that is, the first switches SW11/SW21/SW31 and the second switches SW12/SW22/SW32 are not enabled simultaneously. In addition, the third switches SW13, SW23, and SW33 in the first circuit 210, the second circuit 220, and the third circuit 230 are controlled by a third clock signal CK1d, wherein the third clock signal CK1d is generated based on the first clock signal CK1, for example, the third clock signal CK1d is generated by the first clock signal CK1 through a delay circuit, that is, the phase of the third clock signal CK1d lags behind the phase of the first clock signal CK1. The fourth switches SW14, SW24, and SW34 in the first circuit 210, the second circuit 220, and the third circuit 230 are controlled by a fourth clock signal CK2d, wherein the fourth clock signal CK2d is generated based on the second clock signal CK2, for example, the fourth clock signal CK2d is generated by the second clock signal CK2 through a delay circuit, that is, the phase of the fourth clock signal CK2d lags behind the phase of the second clock signal CK2. Furthermore, in one embodiment, the third clock signal CK1d and the second clock signal CK2 do not have a high voltage level at the same time, and the fourth clock signal CK2d and the first clock signal CK1 do not have a high voltage level at the same time.

In other embodiments, the third switches SW13, SW23, and SW33 in the first circuit 210, the second circuit 220, and the third circuit 230 can also be controlled by the first clock signal CK1, and/or the fourth switches SW14, SW24, and SW34 in the first circuit 210, the second circuit 220, and the third circuit 230 can also be controlled by the second clock signal CK2. These alternative designs should fall within the scope of the present invention.

It is noted that the timing and duty cycle of the plurality of clock signals shown in FIG. 3 are merely provided for illustrative purposes and are not intended as a limitation of the present invention. For example, as long as the first clock signal CK1 and the second clock signal CK2 do not simultaneously enable the corresponding switches (e.g., the first clock signal CK1 and the second clock signal CK2 do not have a high level at the same time), the phase and duty cycle of the first clock signal CK1 and the second clock signal CK2 can vary according to the designer's considerations. Similarly, as long as the third clock signal CK1d and the fourth clock signal CK2d do not simultaneously enable the corresponding switches, the phase and duty cycle of the third clock signal CK1d and the fourth clock signal CK2d can vary according to the designer's considerations.

In the operation of the integrator 130, firstly, the integrator 130 operates in a sampling phase. At this time, the first clock signal CK1 and the third clock signal CK1d can have a high voltage level to respectively enable the first switches SW11, SW21, and SW31 (corresponding to the first clock signal CK1) and the third switches SW13, SW23, and SW33 (corresponding to the third clock signal CK1d) in the first circuit 210, the second circuit 220, and the third circuit 230; and the second clock signal CK2 and the fourth clock signal CK2d can have a low voltage level at this time, so that the second switches SW12, SW22, and SW32 (corresponding to the second clock signal CK2) and the fourth switches SW14, SW24, and SW34 (corresponding to the fourth clock signal CK2d) in the first circuit 210, the second circuit 220, and the third circuit 230 are disabled (i.e., in a non-conducting state). During the sampling phase, the voltage difference between the first signal V1 and the common-mode voltage Vcm is stored in the first sampling capacitor Cs1, the second sampling capacitor Cs2, and the third sampling capacitor Cs3.

Furthermore, before the start of the sampling phase, that is, before the third switches SW13, SW23, and SW33 are enabled, the first specific switch SW1 and the second specific switch SW2 are enabled due to the first clock signal CK1, so that the second terminals N12, N22, and N32 in the first circuit 210, the second circuit 220, and the third circuit 230 are connected to each other to average their charges, that is, to make the second terminals N12, N22, and N32 have the same or similar voltage levels.

Immediately following the sampling phase, the integrator 130 operates in an integration phase. At this time, the first clock signal CK1 and the third clock signal CK1d can have a low voltage level, so that the first switches SW11, SW21, and SW31 and the third switches SW13, SW23, and SW33 in the first circuit 210, the second circuit 220, and the third circuit 230 are disabled (i.e., in a non-conducting state); and the second clock signal CK2 and the fourth clock signal CK2d can have a high voltage level at this time to respectively enable the second switches SW12, SW22, and SW32 and the fourth switches SW14, SW24, and SW34 in the first circuit 210, the second circuit 220, and the third circuit 230. During the integration phase, the stored charge difference between the input signal Vin’ and the feedback signal VFB on the first sampling capacitor Cs1, the second sampling capacitor Cs2, and the third sampling capacitor Cs3 can be integrated onto the integration circuit 204 to generate the second signal V2. Specifically, the sampling circuit 202 generates a sampled signal across the sampling capacitors according to stored charge difference on the first sampling capacitor Cs1, the second sampling capacitor Cs2, and the third sampling capacitor Cs3, and the integration circuit 204 is configured to perform an integration operation on the sampled signal to generate the second signal V2.

In the embodiment of FIG. 2, by enabling the first specific switch SW1 and the second specific switch SW2 controlled by the first clock signal CK1 before the start of the sampling phase, the second terminals N12, N22, and N32 can have the same or similar voltage levels, so that the input buffer 110 does not need to have a strong driving capability to transmit the first signal V1 to the first sampling capacitor Cs1, the second sampling capacitor Cs2, and the third sampling capacitor Cs3. For example, assume that before the start of the sampling phase, the three bits D1, D2, and D3 of the output signal Dout are (1, 0, 1) respectively, and the voltage levels of the second terminals N12, N22, and N32 in FIG. 2 are equal to (Vr, 0, Vr). Therefore, before the start of the sampling phase, by enabling the first specific switch SW1 and the second specific switch SW2, the voltage levels of the second terminals N12, N22, and N32 will be equal to (2/3)*Vr. In addition, since the sigma-delta ADC 104 adopts over-sampling technology, that is, the voltage level of the buffered input signal Vin’ is usually very close to (2/3)Vr, the input buffer 110 only requires a lower driving capability to charge and discharge the voltage levels of the second terminals N12, N22, and N32 to the voltage level of the buffered input signal Vin’, thereby reducing the power consumption of the input buffer 110.

In the prior art, due to the absence of the first specific switch SW1 and the second specific switch SW2 for charge averaging, it is necessary during the sampling phase to charge and discharge the second terminal N12 of the first circuit 210 from Vr to the voltage level of the first signal V1, to charge and discharge the second terminal N22 of the second circuit 220 from 0V to the voltage level of the first signal V1, and to charge and discharge the second terminal N32 of the third circuit 230 from Vr to the voltage level of the first signal V1. Therefore, the input buffer 110 requires a stronger driving capability, resulting in very high power consumption.

Briefly summarized, in the integrator of the present invention, by designing a first specific switch SW1 and a second specific switch SW2 with a charge averaging function to be enabled before the start of the sampling phase, and by making the second terminals of the sampling capacitors close to the first signal to be sampled, the input buffer is allowed to require only a lower driving capability to charge and discharge the sampling capacitors to the voltage level of the first signal, thereby reducing the power consumption of the input buffer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrator, comprising:
a sampling circuit, configured to perform a sampling operation on a first signal to generate a sampled signal, and the sampling circuit comprising:
a first circuit comprising a first switch, a second switch, a third switch, a fourth switch, and a first sampling capacitor, wherein the first switch is coupled between a first terminal of the first circuit and a common-mode voltage, the second switch is coupled between the first terminal and a sampling circuit output terminal, the third switch is coupled between a sampling circuit input terminal and a second terminal of the first circuit, the fourth switch is coupled between the second terminal and a first voltage, and the first sampling capacitor is coupled between the first terminal and the second terminal;
a second circuit comprising a first switch, a second switch, a third switch, a fourth switch, and a second sampling capacitor, wherein the first switch is coupled between a first terminal of the second circuit and the common-mode voltage, the second switch is coupled between the first terminal and the sampling circuit output terminal, the third switch is coupled between the sampling circuit input terminal and a second terminal of the second circuit, the fourth switch is coupled between the second terminal and a second voltage, and the second sampling capacitor is coupled between the first terminal and the second terminal; and
a first specific switch, coupled between the second terminal of the first circuit and the second terminal of the second circuit; and
an integration circuit, coupled to the sampling circuit, configured to perform an integration operation on the sampled signal to generate a second signal.

2. The integrator of claim 1, wherein the first switch of the first circuit and the first switch of the second circuit are controlled by a first clock signal, the second switch of the first circuit and the second switch of the second circuit are controlled by a second clock signal, the third switch of the first circuit and the third switch of the second circuit are controlled by a third clock signal, and the fourth switch of the first circuit and the fourth switch of the second circuit are controlled by a fourth clock signal; and
the first clock signal and the second clock signal do not simultaneously enable the corresponding switches.

3. The integrator of claim 2, wherein the third clock signal is generated according to the first clock signal, the fourth clock signal is generated according to the second clock signal, and the third clock signal and the fourth clock signal do not simultaneously enable the corresponding switches.

4. The integrator of claim 3, wherein a phase of the third clock signal lags behind a phase of the first clock signal, and a phase of the fourth clock signal lags behind a phase of the second clock signal.

5. The integrator of claim 4, wherein the first specific switch is controlled by the first clock signal.

6. The integrator of claim 1, wherein before the integrator operates in a sampling phase, the first specific switch is enabled so that the second terminal of the first circuit and the second terminal of the second circuit are connected to each other;
when the integrator operates in the sampling phase, the first switch and the third switch of the first circuit, and the first switch and the third switch of the second circuit are enabled, and the second switch and the fourth switch of the first circuit, and the second switch and the fourth switch of the second circuit are disabled; and
when the integrator operates in an integration phase, the first switch and the third switch of the first circuit, and the first switch and the third switch of the second circuit are disabled, and the second switch and the fourth switch of the first circuit, and the second switch and the fourth switch of the second circuit are enabled.

7. The integrator of claim 1, wherein the sampling circuit further comprises:
a third circuit comprising a first switch, a second switch, a third switch, a fourth switch, and a third sampling capacitor, wherein the first switch is coupled between a first terminal of the third circuit and the common-mode voltage, the second switch is coupled between the first terminal and the sampling circuit output terminal, the third switch is coupled between the sampling circuit input terminal and a second terminal of the third circuit, the fourth switch is coupled between the second terminal and a third voltage, and the third sampling capacitor is coupled between the first terminal and the second terminal; and
a second specific switch, coupled between the second terminal of the second circuit and the second terminal of the third circuit.

8. The integrator of claim 7, wherein before the integrator operates in a sampling phase, the first specific switch and the second specific switch are enabled so that the second terminal of the first circuit, the second terminal of the second circuit, and the second terminal of the third circuit are connected to each other;
when the integrator operates in the sampling phase, the first switch and the third switch of the first circuit, the first switch and the third switch of the second circuit, and the first switch and the third switch of the third circuit are enabled, and the second switch and the fourth switch of the first circuit, the second switch and the fourth switch of the second circuit, and the second switch and the fourth switch of the third circuit are disabled; and
when the integrator operates in an integration phase, the first switch and the third switch of the first circuit, the first switch and the third switch of the second circuit, and the first switch and the third switch of the third circuit are disabled, and the second switch and the fourth switch of the first circuit, the second switch and the fourth switch of the second circuit, and the second switch and the fourth switch of the third circuit are enabled.

9. A sigma-delta analog-to-digital converter, comprising:
an input buffer, configured to receive an input signal to generate a buffered input signal;
an adder, configured to subtract a feedback signal from the buffered input signal to generate a first signal;
an integrator, configured to perform sampling and integration operations on the first signal to generate a second signal;
a quantization circuit, configured to generate an output signal according to the second signal; and
a digital-to-analog converter, configured to perform a digital-to-analog conversion operation on the output signal to generate the feedback signal;
wherein the integrator comprises:
a sampling circuit, configured to perform a sampling operation on a first signal to generate a sampled signal, and the sampling circuit comprising:
a first circuit comprising a first switch, a second switch, a third switch a fourth switch, and a first sampling capacitor, wherein the first switch is coupled between a first terminal of the first circuit and a common-mode voltage, the second switch is coupled between the first terminal and a sampling circuit output terminal, the third switch is coupled between a sampling circuit input terminal and a second terminal of the first circuit, the fourth switch is coupled between the second terminal and a first voltage, and the first sampling capacitor is coupled between the first terminal and the second terminal;
a second circuit comprising a first switch, a second switch, a third switch, a fourth switch, and a second sampling capacitor, wherein the first switch is coupled between a first terminal of the second circuit and the common-mode voltage, the second switch is coupled between the first terminal and the sampling circuit output terminal, the third switch is coupled between the sampling circuit input terminal and a second terminal of the second circuit, the fourth switch is coupled between the second terminal and a second voltage, and the second sampling capacitor is coupled between the first terminal and the second terminal; and
a first specific switch, coupled between the second terminal of the first circuit and the second terminal of the second circuit; and
an integration circuit, coupled to the sampling circuit, configured to perform an integration operation on the sampled signal to generate a second signal.

10. The sigma-delta analog-to-digital converter of claim 9, wherein before the integrator operates in a sampling phase, the first specific switch is enabled so that the second terminal of the first circuit and the second terminal of the second circuit are connected to each other; when the integrator operates in the sampling phase, the first switch and the third switch of the first circuit, and the first switch and the third switch of the second circuit are enabled, and the second switch and the fourth switch of the first circuit, and the second switch and the fourth switch of the second circuit are disabled; and when the integrator operates in an integration phase, the first switch and the third switch of the first circuit, and the first switch and the third switch of the second circuit are disabled, and the second switch and the fourth switch of the first circuit, and the second switch and the fourth switch of the second circuit are enabled.
